(19) United States
(12) Patent Application Publication
(10) Pub. No.: US 2011/0233409 A1
(43) Pub. Date: Sep. 29, 2011

(54) QUANTUM CASCADE LASER THAT GENERATES WIDELY VIEWABLE MID-INFRARED LIGHT

(76) Inventors: Miles J. Weida, Poway, CA (US); Salvatore F. Crivello, Poway, CA (US); Paul Larson, Poway, CA (US)

(21) Appl. No.: 13/050,016

(22) Filed: Mar. 17, 2011

Related U.S. Application Data
(60) Provisional application No. 61/317,641, filed on Mar. 25, 2010.

(51) Int. Cl. H01L 27/14; H01S 5/022

(52) U.S. Cl. 250/338.4; 372/45.01

(57) ABSTRACT

A laser source assembly (324) for generating an output beam (326) that is in the mid-infrared range includes a quantum cascade gain media (338), a first lead (340), a second lead (342), and an infrared transmissive potting material (348). The quantum cascade gain media (338) generates the output beam (326) that exits from a first facet (350) of the gain media (338). The first lead (340) and the second lead (342) are electrically connected to the quantum cascade gain media (338). The infrared transmissive potting material (348) encloses and embeds the quantum cascade gain media (338), a portion of the first lead (340), and a portion of the second lead (342). Because theses components are enclosed and retained by the potting material (348), the resulting laser source assembly (324) is stable, rugged, small, portable, easy to manufacture, reliable, and relatively inexpensive to manufacture.

### RELATED INVENTIONS

This application claims priority on U.S. Provisional Application Ser. No. 61/317,641, filed Mar. 25, 2010 and entitled “QUANTUM CASCADE LASER USED TO GENERATE WIDELY VIEWABLE MID-INFRARED LIGHT PULSES”. As far as is permitted, the contents of U.S. Provisional Application Ser. No. 61/317,641 are incorporated herein by reference.

### BACKGROUND

In the visible spectrum, one or more light sources can be used to generate bright flashes of light that are viewable from many directions. Common applications include stop lights, indicator signals on automobiles, or flashing safety beacons worn by bicyclists at night. Unfortunately, light in the visible spectrum is attenuated by inclement conditions, such as fog and smoke.

In contrast, certain wavelengths of mid-infrared light are not attenuated by inclement conditions. Unfortunately, existing mid-infrared laser source assemblies suffer from being unstable, fragile, relatively difficult to manufacture, unreliable, and/or relatively expensive to manufacture. As a result thereof, existing mid-infrared laser source assemblies have not gained wide usage in many of the beacon type applications.

### SUMMARY

The present invention is directed to a laser source assembly for generating an output beam that is in the mid-infrared range. In one embodiment, the laser source assembly includes a quantum cascade gain media, a first lead, a second lead, and an infrared transmissive potting material. The quantum cascade gain media generates the output beam that exits from a first facet of the gain media when power is directed to the gain media. The first lead and the second lead are electrically connected to the quantum cascade gain media. The infrared transmissive potting material encloses and embeds the quantum cascade gain media, a portion of the first lead, and a portion of the second lead.

As provided herein, because the quantum cascade gain media, a portion of the first lead, and a portion of the second lead are enclosed and retained by the potting material, the resulting laser source assembly is stable, rugged, small, portable, easy to manufacture, reliable, and relatively inexpensive to manufacture. Moreover, with this design, the laser source assembly can be designed to generate a wide angle mid-infrared beam that is useful for many applications, including as a beacon. Additionally, in certain embodiments, in order for mid-infrared lasers to be useful as a beacon, it is necessary to reduce the cost for mass production and provide a simple package that gives protection from the elements.

As used herein, in alternative, non-exclusive embodiments, the wide angle of the beam can be at least approximately thirty, ninety, one-hundred and twenty, or one-hundred and eighty degrees. In certain embodiments, the beam is emitted in a cone that covers plus or minus sixty degrees (±60°) of the full plus or minus ninety degrees (±90°) range.

In one embodiment, the potting material can include a curved, lens like area that is positioned in the path of the output beam that exits the first facet of the gain media. With this design, the potting material can tighten the focus of the output beam.

In another embodiment, a lens can be positioned in path of the output beam that exits the first facet of the gain media, and the lens can be enclosed by and embedded within the potting material. With this design, the lens can tighten the focus of the output beam.

In still another embodiment, a feedback assembly can be spaced apart from the quantum cascade gain media to form an external cavity. In this embodiment, the feedback assembly can also be enclosed by and embedded with the potting material. With this design, the feedback assembly can be used to tune the laser assembly to achieve the desired wavelength of the output beam.

The present invention is also directed to an assembly that includes the laser source assembly described above, and a detector assembly that detects light in the mid-infrared range.

In yet another embodiment, the present invention is directed to a method for generating an output beam that is in the mid-infrared range. In this embodiment, the method includes the steps of providing a laser source assembly, and directing power to the laser source assembly. More specifically, the laser source assembly includes (i) a quantum cascade gain media that emits the output beam from a first facet of the gain media when power is directed to the gain media; (ii) a first lead electrically connected to the gain media; (iii) a second lead electrically connected to the gain media; and (iv) an infrared transmissive potting material that encloses and embeds the quantum cascade gain media, a portion of the first lead, and a portion of the second lead. In this embodiment, power is directed to the quantum cascade gain media via the leads to generate the output beam.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a simplified illustration of a search vehicle, a person in a boat on a body of water, and a search and rescue assembly having features of the present invention;

FIG. 2 is a simplified illustration of an identification vehicle, a person on the ground, a military vehicle, and a field identification system having features of the present invention;

FIG. 3A is a simplified illustration of a first embodiment of a laser source assembly having features of the present invention;

FIG. 3B is a simplified perspective view of a portion of the laser source assembly of FIG. 3A;

FIG. 4 is a simplified illustration of another embodiment of a laser source assembly having features of the present invention;

FIG. 5 is a simplified illustration of yet another embodiment of a laser source assembly having features of the present invention;

FIG. 6 is a simplified illustration of still another embodiment of a laser source assembly having features of the present invention;

FIG. 7 is a simplified graph that illustrates demonstrated wavelength coverage for laser source assemblies having features of the present invention; and

FIG. 8 is a simplified illustration of an output beam exiting a laser source having features of the present invention.

### DESCRIPTION

As an overview, the present invention is directed to a mid-infrared laser source assembly that can be used as a beacon, in conjunction with a mid-infrared detector assembly for surveillance, targeting, navigation, identification, and search and rescue. For example, for surveillance, one or more mid-infrared beacons could be used to define a search area for the detector assembly. With this design, something moving in front of the beacon would result in a disappearance of signal that could be used to trigger an event, much like near-infrared diodes are used in applications such as making sure that the path is clear before closing a garage door.

Alternatively, for targeting, a mid-infrared beacon could be placed on a target of interest surreptitiously, and left operating for later targeting with a mid-infrared sensor. Still alternatively, for navigation, one or more mid-infrared sensors can be used to help navigate in conditions of dust and fog. In this design, multiple mid-infrared beacons could be used to define roads or runways. In yet another alternative design, for identification, in military operations, it is important to identify friend or foe. In this design, the vehicles and/or soldiers could have mid-infrared beacons that identify the owner as friendly. In still another design, in search and rescue, life rafts, life vests, or soldier's kits could all include mid-infrared beacons that could be activated in an emergency. With this design, the emitted signal would allow easier spotting, and could also be invisible to hostile forces if mid-infrared imagers are not widely used. In this design, the mid-infrared beams can be viewed day and night, and in inclement conditions for search and rescue operations.

As provided herein, in certain embodiments, the mid-infrared laser source assemblies provided herein exhibit one or more of the following qualities: low price in mass production, high efficiency for battery operation, high spectral brightness to provide “color” or wavelength-specific signals, and high output powers in pulsed mode for transmitting long distances.

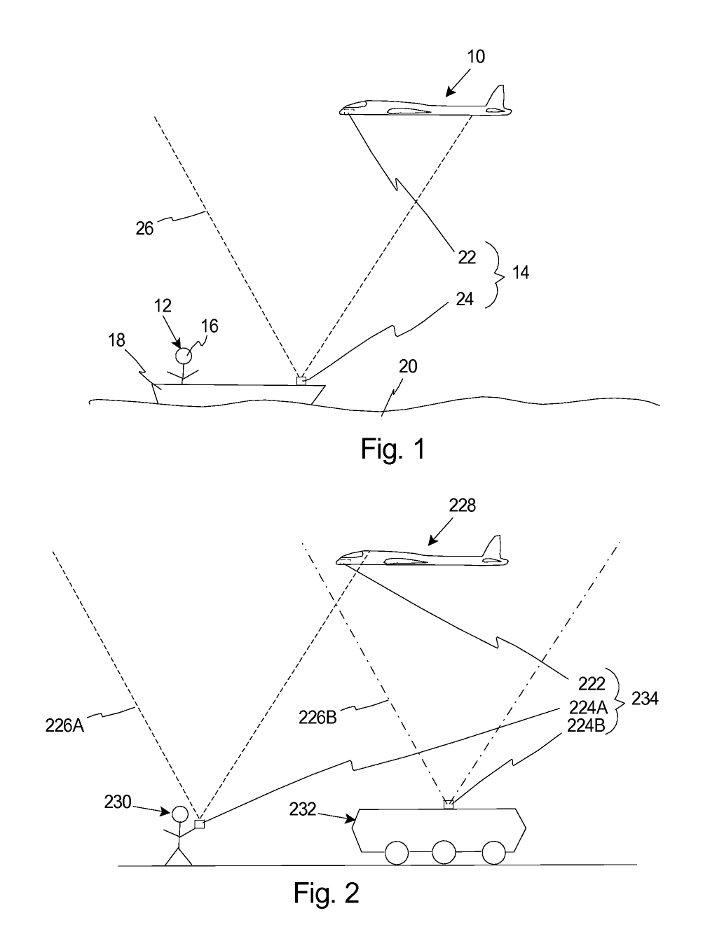

FIG. 1 is a simplified illustration of a search and rescue type system that includes a search vehicle 10, a search object 12, and a search and rescue assembly 14 having features of the present invention. In this example, the search and rescue assembly 14 is used by the people in the search vehicle 10 to locate the search object 12. The type of search vehicle 10 and/or the type of search object 12 can be varied. In the non-exclusive example illustrated in FIG. 1, the search vehicle 10 is an aircraft, and the search object 12 is a person 16 in a boat 18 on a body of water 20. In this embodiment, the search and rescue assembly 14 includes a detector assembly 22 (illustrated as a box in phantom) that is carried by the search vehicle 10, and a laser source assembly 24 that is positioned by the search object 12. More specifically, in this embodiment, (i) the laser source assembly 24 is a mid-infrared beacon that generates a wide angle, pulsed mid-infrared output beam 26, and (ii) the detector assembly 22 is a thermal detector, e.g. a mid-infrared camera (based on micro-bolometer and cooled mercury-cadmium-telluride (MCT) arrays for example) that detects the mid-infrared beam 26.

As provided herein, the wide angle of pulsed mid-infrared beam 26 created by the laser source assembly 24 provides a wide angle of view for the search vehicle 10. Moreover, as provided herein, the laser source assembly 24 is uniquely designed to provide high peak pulse intensities that enable viewing of the beam 26 over large distances. Moreover, the laser source assembly 24 is uniquely designed to be lightweight, stable, rugged, small, portable, easy to manufacture, reliable, and relatively inexpensive to manufacture. As a result thereof, the laser source assembly 22 can be used in many applications as beacons.

Additionally, as used herein, the mid-infrared beam 26 has a wavelength in the range of approximately 2-20 microns. With this design, the output beam 26 is able to propagate through inclement conditions (e.g. fog, rain, snow, smoke, clouds, or dust in the atmosphere) with minimal absorption. Moreover, the output beam 26 is viewable day and night with the detector assembly 22.

There are many different usages for the laser source assemblies provided herein, only a few of which are specifically illustrated. For example, FIG. 2 illustrates another usage for the laser source assembly. More specifically, FIG. 2 illustrates an identification vehicle 228, a first asset 230, a second asset 232, and a field identification system 234 that can be used to identify and locate the assets 230, 232. In this embodiment, the type of identification vehicle 228 and/or the type of asset 230, 232 can be varied. In the non-exclusive example illustrated in FIG. 2, the identification vehicle 228 is an aircraft, the first asset 230 is a person, and the second asset 232 is a military vehicle. In this embodiment, the field identification system 234 includes a detector assembly 222 (illustrated as a box in phantom) that is carried by the identification vehicle 228, and a first laser source assembly 224A that is carried by the first asset 230, and a second laser source assembly 224B that is carried by the second asset 232.

In this embodiment, (i) the first laser source assembly 224A is a mid-infrared beacon that generates a wide angle, mid-infrared first output beam 226A that is pulsed at a first rate; (ii) the second laser source assembly 224B is a mid-infrared beacon that generates a wide angle, mid-infrared second output beam 226B that is pulsed at a second rate that is different than the first rate; and (iii) the detector assembly 222 is a thermal detector that detects the mid-infrared beams 226A, 226B. With this design, the field identification system 234 can be used to locate and individually identify multiple assets 230, 232 based on the pulse sequence of the output beams 226A, 226B. Moreover, the wide angle of the output beams 226A, 226B allows for multiple assets to be concurrently viewed at once with the detector assembly 222.

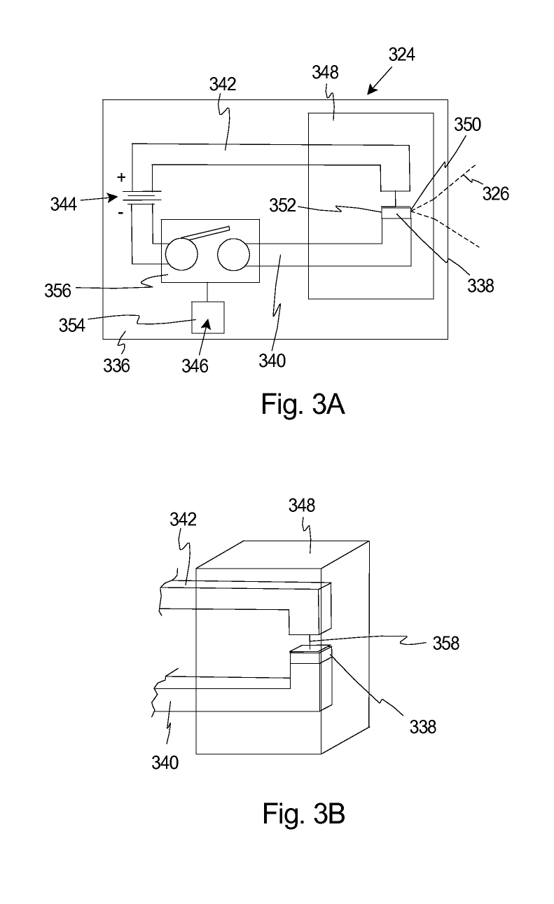

FIG. 3A is one non-exclusive example of a laser source assembly 324 that can be used in the assemblies illustrated in FIGS. 1 and 2 or another type of assembly. In FIG. 3A, the laser source assembly 324 includes a housing 336, a quantum cascade gain media 338, a first lead 340, a second lead 342, a power source 344, a laser controller 346, and a potting material 348. The design of each of these components can be varied pursuant to the teachings provided herein.

In certain embodiments, because of the design of the laser source assembly 324 provided herein, the overall size is quite small. For example, the laser source assembly 324 can have dimensions of approximately 20 centimeters (height) by 20 centimeters (width) by 20 centimeters (length) (where length is taken along the propagation direction of the laser beam) or less, and more preferably, the laser source assembly 324 has dimensions of approximately 3 centimeters (height) by 4 centimeters (width) by 5 centimeters (length). Still alternatively, the laser source assembly 324 can have dimensions of less than approximately 10 millimeters (height) by 25 millimeters (width) by 30 millimeters.

In one embodiment, the laser source assembly 324 would have a form factor like a battery-powered flashing light for a bike.

The housing 336 supports and provides a rigid platform for at least some of the components of the laser source assembly 324. In FIG. 3A, the housing 336 is illustrated as being generally flat plate shaped. In this embodiment, the housing 336 is a monolithic structure that provides structural integrity to the laser source assembly 324. Alternatively, the housing 336 can have a configuration that is different than that illustrated in FIG. 3A.

The quantum cascade gain media 338 is a unipolar semiconductor laser that includes a series of energy steps built into the material matrix while the crystal is being grown. As used herein the term quantum cascade gain media 338 shall also include Interband Cascade Lasers (ICL). ICL lasers use a conduction-band to valence-band transition as in the traditional diode laser. In one, non-exclusive embodiment, the quantum cascade gain media 338 is mounted epitaxial growth side down and has a length of approximately four millimeters, a width of approximately one millimeter, and a height of approximately one hundred microns. A suitable quantum cascade gain media 338 can be purchased from Alpes Lasers, located in Switzerland.

As provided herein, the quantum cascade gain media 338 can generate the mid-infrared output beam 326 without active cooling. A quantum cascade gain media 338 generates light by dropping an electron through designed energy levels that are immune to swamping by thermal carriers. Room temperature operation is possible with the quantum cascade gain media 338, and wall-plug efficiencies (light power out compared to electrical power in) as high as twenty three percent have been reached for pulsed room temperature operation of the quantum cascade gain media 338. Moreover, the quantum cascade gain media 338 is semiconductor based, can generate hundreds of milliwatts of optical power with high efficiency, and can be designed to create light across the mid-infrared spectrum.

In FIG. 3A, the quantum cascade gain media 338 includes (i) a first facet 350 that emits the mid-infrared beam 326, and (ii) a second facet 352 that reflects light back towards the first facet 350. In FIG. 3A, (i) the first facet 350 is uncoated or is coated with a partly reflective coating that allows some photons to exit the first facet 350, and (ii) the second facet 352 is coated with a highly reflective coating that inhibits the photons from exiting the second facet 352, reflecting them back into the wave guide to facilitate lasing. In one non-exclusive example, the high reflective coating can have a reflectivity of greater than approximately 95 percent for the wavelength of the quantum cascade gain media 338. In this embodiment, the laser source assembly 324 does not have an external cavity.

The leads 340, 342 electrically connect the power source 344 and the laser controller 346 to the quantum cascade gain media 338. In one embodiment, each lead 340, 342 is made of a rigid, electrically conductive material, such as tin or copper, for example.

The power source 344 provides electrical power for the quantum cascade gain media 338, and the laser controller 346. In FIG. 3A, the power source 344 is a battery that is secured to the housing 336. For example, the battery can be nickel metal hydrate. Alternatively, for example, the power source 344 can be a power outlet, an external battery, and/or a generator of a vehicle.

The laser controller 346 controls the operation of the laser source assembly 324 including the electrical power that is directed to the quantum cascade gain media 338. For example, the laser controller 346 can include a processor 354 and a switch 356. In this design, the processor 354 controls the quantum cascade gain media 338 by controlling the electron injection current via the switch 356. For example, the laser controller 346 can direct power to the gain media 338 in a pulsed fashion to minimize heat generation in, and power consumption of the gain media 338, while still achieving the desired average optical power of the output beam 326. This allows the gain media 338 to be sufficiently powered by a battery for a longer period of time than when used in a continuous wave (CW) mode of operation. Moreover, with this design, the gain media 338 operates efficiently because it is not operating at a high temperature, and the need to actively cool the gain media 338 is eliminated in certain embodiments. Alternatively, the laser controller 346 can be in a CW mode of operation.

Benefits of operation of the gain media 338 in pulsed fashion include increased efficiency, lower thermal loads to dissipate in the beacon, and higher peak optical powers. Moreover, low battery drain is crucial for long beacon lifetime in the field.

In certain embodiments, the switch 356 is a fast switch, such as a field effect transistor (“FET”), can provide voltage pulses as short as 10 nsec. The quantum cascade gain media 338 works at peak efficiency for voltage pulses of ≦500 nsec, before the active region of the gain media 338 begins to heat up. Fast switching times are achievable with this voltage-switched circuit, further reducing heat generation and battery drain when the beacon is off. Finally, pulse generation electronics can be used to drive the switch to generate arbitrary pulse sequences that might be needed for a certain type of beacon identification.

The potting material 348 provides a rigid platform that supports one or more of the components of the light source assembly 10 and maintains the relative position of these components of the laser source assembly 10. In one embodiment, the potting material 348 fixedly secures in a rigid arrangement, and fully encloses the gain media 338 and a portion of the leads 340, 342. Stated in another fashion, the leads 340, 342 and the quantum cascade gain media 338 are given stability by the potting material 348. Further, with this design, the potting material 348 maintains these components in precise mechanical alignment. Moreover, the potting material 348 provides shock and vibration protection for these components, and protects these components from moisture and corrosive agents.

The design and material utilized for the potting material 348 can be varied pursuant to the teachings provided herein. In one embodiment, the potting material 348 is infrared transmissive. As a result thereof, the output beam 326 from the quantum cascade gain media 338 is allowed to diverge as it exits the quantum cascade gain media 338 for beacon applications. It should be noted that in this embodiment, there is no collimation lens positioned in the path of the output beam 326. Thus, the output beam 326 provides wide angle of view for search and rescue vehicles with mid-infrared detectors.

There are many options for mid-infrared transmissive potting materials 348. Non-exclusive examples of suitable mid-infrared transmissive materials include, but are not limited to, PTFE, polyethylene, polypropylene, and polyvinyl chloride.

FIG. 3B is a perspective view of the potting material 348, and the gain media 338, and a portion of the leads 340, 342 embedded with the potting material 348. In this embodiment, the potting material 348 is generally rectangular shaped. Alternatively, the size and shape of the potting material 348 can be different than that illustrated in FIG. 3B. For example, the potting material 348 can be cylindrical shaped.

It should be noted that with the embodiments disclosed herein, the packaging with the potting material 348 allows for high volume, and low cost production of the laser source assembly 324. As illustrated in FIG. 3B, the quantum cascade gain media 338 is directly and fixedly mounted to the first lead 340. Further, the second lead 342 is bonded to the quantum cascade gain media 338 with a wire 358, then the entire assembly potted in the mid-infrared transmissive potting material 348. Benefits of this design of the potting material 348 include, but are not limited to: (i) providing mechanical stability for the quantum cascade gain media 338 and the leads 340, 342; (ii) removing heat from the quantum cascade gain media 338 and the leads 340, 342; (iii) protecting the quantum cascade gain media 338 and the leads 340, 342 from the environment; (iv) shaping and enhancing the beam divergence of the output beam 326; and/or (v) providing a more focused output beam 326.

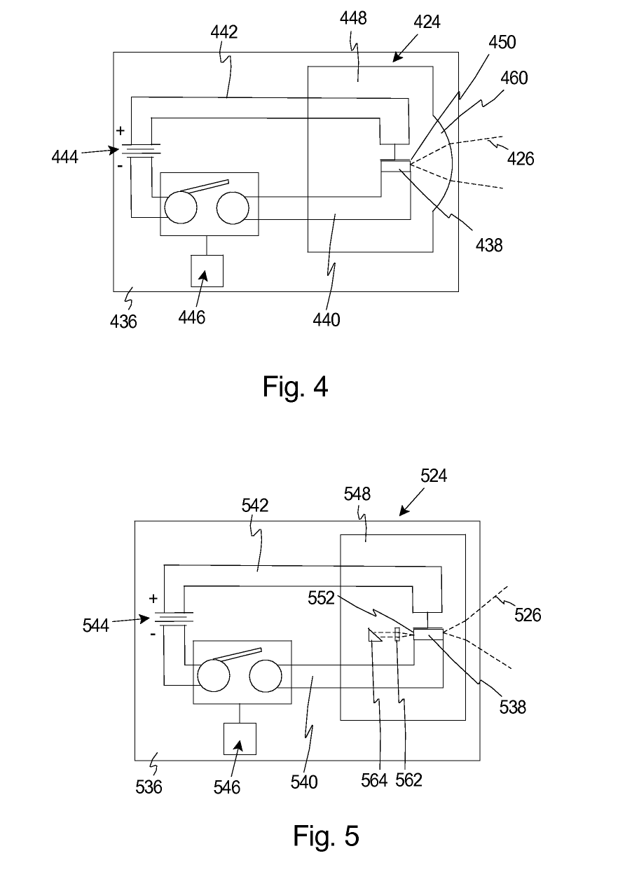

FIG. 4 is a simplified illustration of another embodiment of a laser source assembly 424 that can be used in the assemblies illustrated in FIGS. 1 and 2 or another type of assembly. In FIG. 4, the laser source assembly 424 includes a housing 436, a quantum cascade gain media 438, a first lead 440, a second lead 442, a power source 444, a laser controller 446, and a potting material 448 that are somewhat similar to the corresponding components described above and illustrated in FIGS. 3A and 3B. However, in this embodiment, a portion of the potting material 448 has been shaped to include a lens like area 460 that provides some lensing properties for tightening the focus of the output beam 426. In this embodiment, the lens like area 460 is positioned in front of the first facet 450 of the quantum cascade gain media 438 and the lens like area 460 is positioned in the path of the output beam 426. As a non-exclusive example, the lens like area 460 can have a curved shaped that at least partly collimates the output beam 426. In this design, the lens like area 460 is able to tighten the focus of the output beam 426 because the potting material 448 has an index of refraction that is higher than the index of refraction of air.

It should be noted that the shaped and curvature of the lens like area 460 can be varied to achieve the desired level of shaping of the output beam 426. As for beam tightening, as one non-exclusive example, the lens like area 460 can be used to reduce the divergence of the output beam 426 from an approximately ninety degree (90°) divergence to an approximately thirty degree (30°) divergence. But the design can be changed to accommodate different amounts of beam shaping.

FIG. 5 is a simplified illustration of another embodiment of a laser source assembly 524 that can be used in the assemblies illustrated in FIGS. 1 and 2 or another type of assembly. In FIG. 5, the laser source assembly 524 includes a housing 536, a quantum cascade gain media 538, a first lead 540, a second lead 542, a power source 544, a laser controller 546, and a potting material 548 that are somewhat similar to the corresponding components described above and illustrated in FIGS. 3A and 3B. However, in this embodiment, the laser source assembly 524 is an external cavity type assembly that includes a collimating lens 562 and a feedback assembly 564 that are also embedded within and fixedly retained in position with the potting material 548. In this embodiment, the second facet 552 is coated with an anti-reflective coating that allows light directed from the gain media 538 at the second facet 552 to easily exit the gain media 538 and allows the light reflected from the feedback assembly 564 to easily enter the QC gain media 538. In one non-exclusive embodiment, the anti-reflective coating can have a reflectivity of less than approximately 2 percent.

In this embodiment, the light exiting from the second facet 552 is collimated by the lens 562 onto the feedback assembly 564 and light reflected from the feedback assembly 564 and directed at the lens 562 is focused on the second facet 552. In this embodiment, the lens 562 is positioned between the gain media 538 and the feedback assembly 564 along the lasing axis. For example, the lens 562 can be an aspherical lens having an optical axis that is aligned with the lasing axis. The lens 562 can comprise materials selected from the group of Ge, ZnSe, ZnS Si, CaF, BaF or chalcogenide glass. However, other materials may also be utilized.

The feedback assembly 564 reflects the light back to the quantum cascade gain media 538, and is used to precisely adjust the lasing frequency of the external cavity and the wavelength of the output beam 526. In this manner, the output beam 526 is tuned and set to a desired fixed wavelength with the feedback assembly 564. Thus, in this external cavity arrangement, the feedback assembly 564 dictates what wavelength will experience the most gain and thus dominate the wavelength of the output beam 526.

The design of the feedback assembly 564 can vary pursuant to the teachings provided herein. Non-exclusive examples of a feedback assembly 564 includes a diffraction grating, a MEMS grating, prism pairs, a thin film filter stack with a reflector, an acoustic optic modulator, or an electro-optic modulator. The type of adjustment done to the feedback assembly 564 to adjust the lasing frequency of the external cavity will vary according to the type of feedback assembly 564. For example, if the feedback assembly 564 is a diffraction grating, rotation of the diffraction grating relative to the lasing axis and the quantum cascade gain media 538 adjusts the lasing wavelength and the wavelength of the output beam 526. With this design, the feedback assembly 564 can be adjusted prior to enclosing with the potting material 548 to achieve the desired center wavelength of the output beam 526. As a result thereof, the laser source assembly 524 can be tuned so that the output beam 526 has a wavelength that is not absorbed by the inclement conditions in the atmosphere.

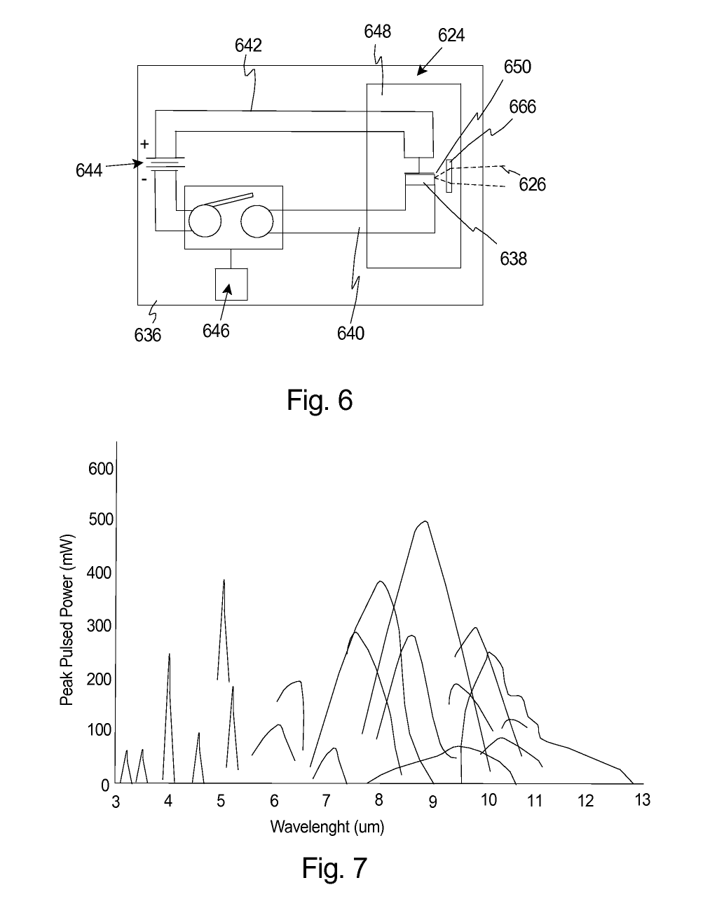

FIG. 6 is a simplified illustration of still another embodiment of a laser source assembly 624 that can be used in the assemblies illustrated in FIGS. 1 and 2 or another type of assembly. In FIG. 6, the laser source assembly 624 includes a housing 636, a quantum cascade gain media 638, a first lead 640, a second lead 642, a power source 644, a laser controller 646, and a potting material 648 that are somewhat similar to the corresponding components described above and illustrated in FIGS. 3A and 3B. However, in this embodiment, the laser source assembly 624 includes an output lens 666 that is also embedded within and fixedly retained in position with the potting material 648. In this embodiment, the output lens 666 is positioned in front of the first facet 650 of the quantum cascade gain media 638 and the output lens 666 is positioned in the path of the output beam 626. As a non-exclusive example, the output lens 666 can collimate and focus the output beam 626. As non-exclusive examples, the output lens 666 can be made of a material selected from the group of Ge, ZnSe, ZnS Si, CaF, BaF or chalcogenide glass. However, other materials may also be utilized.

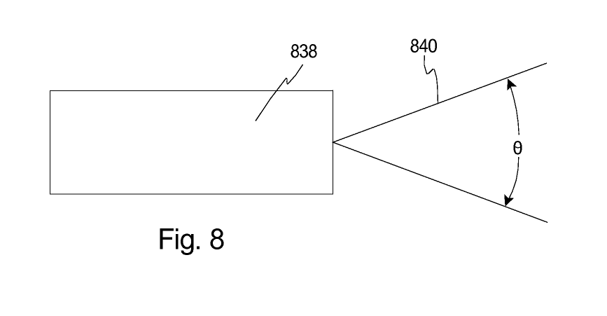

FIG. 7 is a graph that illustrates demonstrated wavelength coverage for quantum cascade gain media operated in pulsed mode.

FIG. 8 is a simplified illustration of an output beam 826 exiting a quantum cascade gain media 838. In this embodiment, the output beam 826 is emitted from the gain media 838 in a cone that covers the angle θ.

While the particular laser source assembly 10 as shown and disclosed herein is fully capable of obtaining the objects and providing the advantages herein before stated, it is to be understood that it is merely illustrative of the presently preferred embodiments of the invention and that no limitations are intended to the details of construction or design herein shown other than as described in the appended claims.

What is claimed is:

1. A laser source assembly for generating an output beam that is in the mid-infrared range, the laser source assembly comprising:
a quantum cascade gain media that generates the output beam that exits from a first facet of the gain media when power is directed to the gain media;
a first lead and a second lead that are electrically connected to the quantum cascade gain media; and
an infrared transmissive potting material that encloses and embeds the quantum cascade gain media, a portion of the first lead, and a portion of the second lead.

2. The laser source assembly of claim 1 wherein the potting material includes a curved, lens like area that is positioned in the path of the output beam that exits the first facet of the gain media, the lens like area tightening the focus of the output beam.

3. The laser source assembly of claim 1 further comprising a lens positioned in path of the output beam that exits the first facet of the gain media, and wherein the lens is enclosed by and embedded within the potting material.

4. The laser source assembly of claim 1 further comprising a feedback assembly spaced apart from the quantum cascade gain media to form an external cavity, and wherein the feedback assembly is enclosed by and embedded with the potting material.

5. The laser source assembly of claim 1 further comprising a battery electrically connected to the first lead and the second lead.

6. The laser source assembly of claim 1 wherein the quantum cascade gain media is directly secured to the first lead.

7. The laser source assembly of claim 1 further comprising a laser controller that directs pulses of power to the quantum cascade gain media.

8. An assembly comprising the laser source assembly of claim 1 and a detector assembly that detects light in the mid-infrared range.

9. A method for generating an output beam that is in the mid-infrared range, the method comprising the steps of:
providing a laser source assembly that includes (i) a quantum cascade gain media that emits the output beam from a first facet of the gain media when power is directed to the gain media; (ii) a first lead electrically connected to the gain media; (iii) a second lead electrically connected to the gain media; and (iv) an infrared transmissive potting material that encloses and embeds the quantum cascade gain media, a portion of the first lead, and a portion of the second lead; and
directing power to the quantum cascade gain media via the leads to generate the output beam.

10. The method of claim 9 wherein the step of providing includes the potting material having a curved, lens like area that is positioned in the path of the output beam that exits the first facet of the gain media, the lens like area tightening the focus of the output beam.

11. The method of claim 9 wherein the step of providing includes a lens positioned in path of the output beam that exits the first facet of the gain media, and wherein the lens is enclosed by and embedded within the potting material.

12. The method of claim 9 wherein the step of providing includes a feedback assembly positioned spaced apart from the quantum cascade gain media to form an external cavity, and wherein the feedback assembly is enclosed by and embedded with the potting material.

13. The method of claim 9 wherein the step of directing power includes the step of electrically connecting a battery to the first lead and the second lead.

14. The method of claim 9 wherein the step of providing includes the quantum cascade gain media being directly secured to the first lead.

15. The method of claim 9 wherein the step of directing power includes the step of directing pulses of power to the quantum cascade gain media.
